(19) United States
(12) Patent Application Publication
(10) Pub. No.: US 2010/0171510 A1
(43) Pub. Date: Jul. 8, 2010

(54) TESTING APPARATUS AND TESTING METHOD

(75) Inventors: Zhong REN, SHANGHAI (CN); Xue-Hui HU, SHANGHAI (CN)

Correspondence Address: BRIAN M. MCINNIS, 12th Floor, Ruttonjee House, 11 Duddell Street, Hong Kong, HK

(73) Assignee: Inventec Appliances Corp., Taipei Hsien (TW)

(21) Appl. No.: 12/649,362

(22) Filed: Dec. 30, 2009

(30) Foreign Application Priority Data
Jan. 7, 2009 (TW) 98100409

(51) Int. Cl. G01R 31/02; G01R 19/22

(52) U.S. Cl. 324/537; 324/120

(57) ABSTRACT

A testing apparatus and a testing method are described and shown in the specification and drawing. The testing apparatus includes in-circuit testing equipment and a converter. The converter electrically connects an electric circuit and the in-circuit testing equipment. The in-circuit testing equipment includes an in-circuit testing module, a test instruction generation module and an feedback signal analysis module. The in-circuit testing module tests hardware of the electric circuit. The test instruction generation module sends a test instruction to the electric circuit through the converter when the electric circuit is supplied with power and after the hardware of the electric circuit passes the test by the in-circuit testing module, so that the electric circuit generates a feedback signal. The feedback signal analysis module receives the feedback signal through the converter and analyzes, according to the feedback signal, whether the electric circuit performs according to the electric circuit's intended function.

### RELATED APPLICATIONS

This application claims priority to Taiwan Application Serial Number 98100409, filed Jan. 7, 2009, which is herein incorporated by reference.

### BACKGROUND

1. Technical Field

The present disclosure relates to a testing apparatus and a testing method, and more particularly to a testing apparatus and a testing method for testing an electric circuit.

2. Description of Related Art

With the fast development of the electronics industry, the application of printed circuit boards (PCBs) has become more popular. PCBs are rugged, inexpensive, and can be highly reliable. They require much more layout effort and higher initial cost than either wire-wrapped or point-to-point constructed circuits, but are much cheaper and faster for high-volume production.

Much of the electronics industry's PCB design, assembly, and quality control needs are set by standards. In general, in-circuit testing equipment is an example of white box testing where an electrical probe tests a populated printed circuit board (PCB), checking for shorts, opens, resistance, capacitance, and other basic quantities which will show whether the assembly was correctly fabricated. It may be performed with a bed of nails type test fixture and specialist test equipment, or with a fixtureless in-circuit test setup. However, the conventional in-circuit testing equipment is incapable of testing the function of PCB, such as program errors and the functions of a power module, operational amplifiers and integrated circuits.

In view of the foregoing, there is an urgent need in the related field to refit in-circuit testing equipment, so as to perform function tests. The present disclosure meets this need.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one aspect, the present disclosure is directed to a testing apparatus, in which in-circuit testing equipment is refitted to perform function tests for an electric circuit.

According to one embodiment of the present invention, the testing apparatus includes in-circuit testing equipment and a converter. The in-circuit testing equipment includes an in-circuit testing module, a test instruction generation module and a feedback signal analysis module.

In this embodiment, the in-circuit testing equipment is electrically connected to the converter, and the converter is electrically connected to the electric circuit and is for converting signals.

When in use, the in-circuit testing module can test hardware of the electric circuit. The test instruction generation module can send a test instruction to the electric circuit through the converter when the electric circuit is supplied with power and after the hardware of the electric circuit passes the test by the in-circuit testing module, so that the electric circuit generates a feedback signal. The feedback signal analysis module can receive the feedback signal through the converter and analyze, according to the feedback signal, whether the electric circuit performs according to the electric circuit's intended function.

In this way, the testing apparatus can both test the hardware and the function of the electric circuit, so as to test the electric circuit more efficiently. Thus, the production efficiency is improved, and furthermore the production cost is reduced.

In another aspect, the present disclosure is directed to a testing method adapted in in-circuit testing equipment, so as to perform function tests for the electric circuit.

According to another embodiment of the present invention, the testing method includes steps as follows. First, hardware of an electric circuit is tested. Next, a test instruction is sent to the electric circuit through a converter when the electric circuit is supplied with power and after the hardware of the electric circuit passes the testing, so that the electric circuit generates a feedback signal, wherein the converter is for converting signals. Then, the feedback signal is received through the converter. Finally, whether the electric circuit performs according to the electric circuit's intended function is analyzed according to the feedback signal.

In this way, the testing method is performed to test the hardware and the function of the electric circuit, so as to test the electric circuit more efficiently. Thus, the production efficiency is improved, and furthermore the production cost is reduced.

Many of the attendant features will be more readily appreciated as the same becomes better understood by reference to the following detailed description considered in connection with the accompanying drawings.

### BRIEF DESCRIPTION OF THE DRAWINGS

The present description will be better understood from the following detailed description read in light of the accompanying drawings, wherein:

FIG. 1 is a functional block diagram illustrating a testing apparatus according to one embodiment of the present invention;

FIG. 2 is a functional block diagram of the feedback signal analysis module of FIG. 1;

FIG. 3 is a flowchart illustrating a testing method according to another embodiment of the present invention; and FIG. 4 is a flowchart of step 250 of FIG. 3.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In one aspect, the present disclosure is directed to a testing apparatus. The testing apparatus can test a printed circuit board (PCB), a printed circuit board assembly (PCBA) or the like, and may be applicable or readily adaptable to all technology.

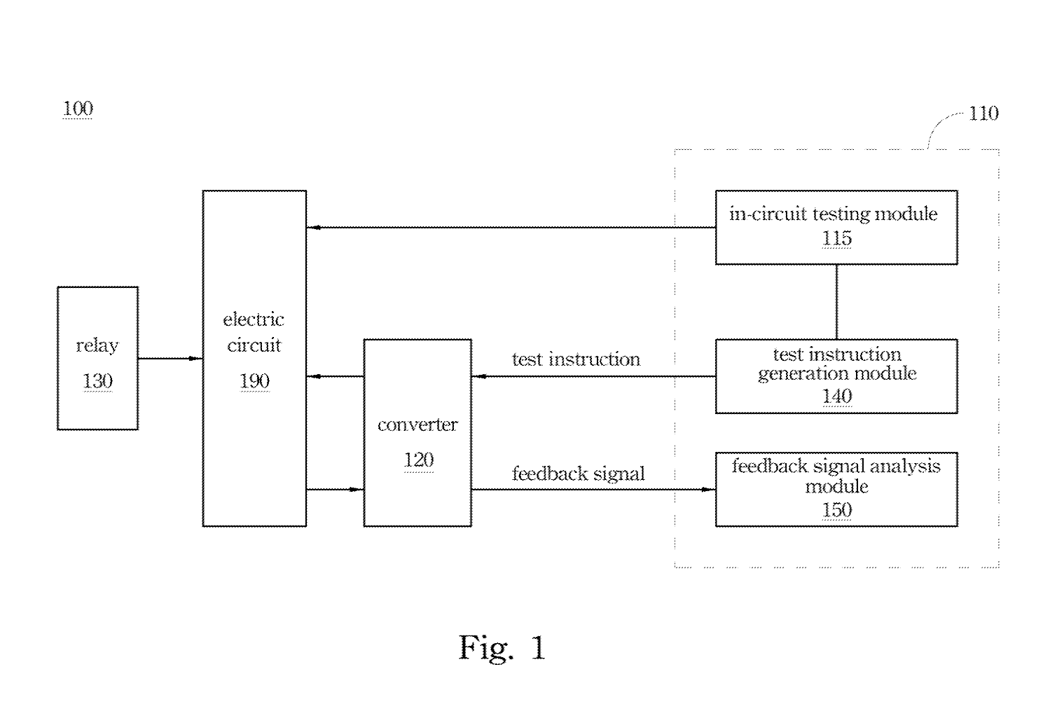

Please refer to FIG. 1 which is a functional block diagram illustrating a testing apparatus 100 according to one embodiment of the present invention. As shown in FIG. 1, the testing apparatus 100 includes in-circuit testing equipment 110 and a converter 120. The in-circuit testing equipment 110 comprises an in-circuit testing module 115, a test instruction generation module 140 and an feedback signal analysis module 150.

In this embodiment, the in-circuit testing equipment 110 is electrically connected to the converter 120, and the converter 120 is electrically connected to an electric circuit 190 and is for converting signals.

When in use, the in-circuit testing module 115 can test hardware of the electric circuit 190. The test instruction generation module 140 can send a test instruction to the electric circuit 190 through the converter 120 when the electric circuit 190 is supplied with power and after the hardware of the electric circuit 190 passes the test by the in-circuit testing module 115, so that the electric circuit 190 generates a feedback signal. The feedback signal analysis module 150 can receive the feedback signal through the converter 120 and analyze, according to the feedback signal, whether the electric circuit 190 performs according to the electric circuit's intended function.

In this way, the testing apparatus 100 can both test the hardware and the function of the electric circuit 190, so as to test the electric circuit 190 more efficiently. Thus, the production efficiency is improved, and furthermore the production cost is reduced.

The in-circuit testing module 115 is configured to test the hardware of the electric circuit 190 for checking short-circuits, open-circuits, wiring lines, protection diodes, solder joints of integrated circuits, or the like. The processes of testing the hardware of the electric circuit are well known in the art and, thus, are not repeated herein.

The test instruction generation module 140 and the feedback signal analysis module 150 are configured to test the function of the electric circuit 190, such as program errors and the functions of a power module, operational amplifiers and integrated circuits. In this embodiment, the testing apparatus 100 can provide varied test instructions for testing the electric circuit 190 and then analyze feedback signals, so as to test the various functions of the electric circuit 190, such as version, RAM, flash memory, RNG, battery voltage, temperature or the like. It should be appreciated that the above test items are only examples and should not be regarded as limitations of the present invention. Those with ordinary skill in the art may add or delete test items depending on the desired application.

In practice, the in-circuit testing module 115, the test instruction generation module 140 and the feedback signal analysis module 150 may be integrated in software programs and/or hardware circuitry of the in-circuit testing equipment 110. Those with ordinary skill in the art may select the desired implementation which could be software programs, hardware circuitry or a portion of software programs and a portion of hardware circuitry.

The converter 120 can be manufactured in one circuit board. In this embodiment, the converter 120 could be an RS-232-to-TTL(Transistor-transistor logic) converter. If the electric circuit 190 itself had no chip of RS-232-to-TTL, the test instruction generation module 140 sends a test instruction to the electric circuit 190 through the RS-232-to-TTL converter, and furthermore the feedback signal analysis module 150 receives the feedback signal through the RS-232-to-TTL converter to analyze whether the electric circuit performs according to the electric circuit's intended function. In an alternative embodiment, the converter 120 may be a general purpose interface bus (GPIB) or the like.

The electric circuit 190 may be a portion of the circuitry of the printed circuit board or the entire circuitry of the printed circuit board (PCB); alternatively, the electric circuit 190 may be a portion of printed circuit board assembly (PCBA). It should be appreciated that said PCB and PCBA are only examples and should not be regarded as limitations of the present invention. Those with ordinary skill in the art may select an electric circuit 190 depending on the desired application.

Still refer to FIG. 1. The testing apparatus 100 may comprise a relay 130. In construction of the testing apparatus 100, the relay 130 is electrically connected to the electric circuit 190. When in use, the relay 130 can relay electric power to the electric circuit 190.

The relay 130 can be manufactured in one circuit board. In this embodiment, the single relay 130 can be electrically connected to a plurality of electric circuits and selectively relay electric power to at least one of said electric circuits. For example, the relay 130 relays electric power to the electric circuit 190, so that the test instruction generation module 140 and the feedback signal analysis module 150 test the function of the electric circuit 190.

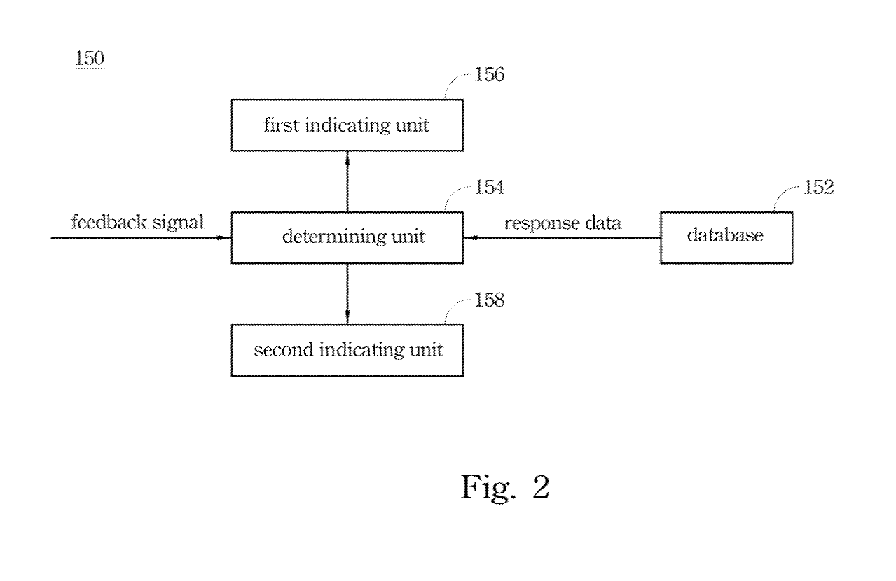

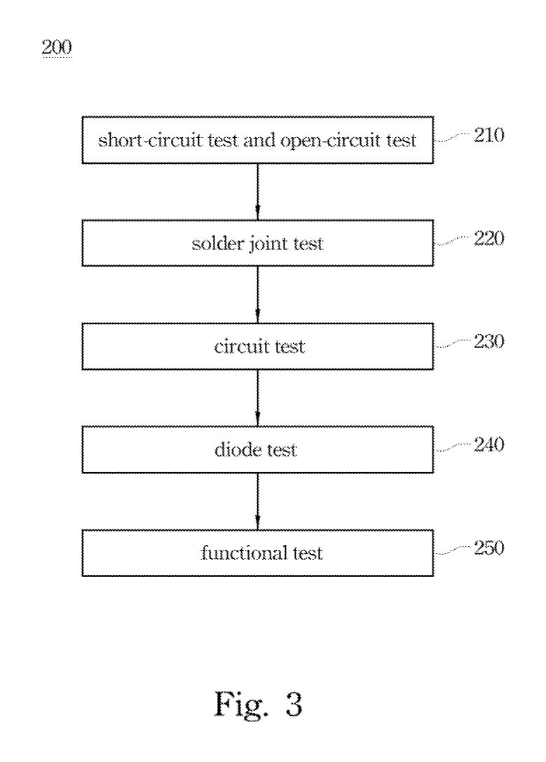

For a more complete understanding of the feedback signal analysis module 150, please refer to FIG. 2 that is a functional block diagram of the feedback signal analysis module 150 of FIG. 1. As shown in FIG. 2, the feedback signal analysis module 150 comprises a database 152, a determining unit 154, a first indicating unit 156 and a second indicating unit 158.

When in use, the database 152 can store response data, wherein the response data represents the feedback signal that is generated by the electric circuit 190 while the electric circuit 190 performs according to the electric circuit's intended function. The determining unit 154 can determine whether the feedback signal corresponds to the response data. The first indicating unit 156 can indicate that the electric circuit 190 performs according to the electric circuit's intended function when it's determined that the feedback signal corresponds to the response data; on the contrary, the second indicating unit 158 can indicate that the electric circuit 190 does not perform according to the electric circuit's intended function when it's determined that the feedback signal does not correspond to the response data.

The database 152 may comprise a data storage component for storing response data. It should be appreciated that said data storage component is only an example and should not be regarded as limitations of the present invention. Those with ordinary skill in the art may design the database 152 depending on the desired application.

The first and second indicating unit 156 and 158 may comprise a monitor, so that the screen of the monitor can display the information of whether the electric circuit 190 performs according to the electric circuit's intended function. Alternatively, the first and second indicating unit 156 and 158 may comprise a dichromatic LED; for example, the dichromatic LED emits red light when the electric circuit 190 does not perform according to the electric circuit's intended function, or the dichromatic LED emits green light when the electric circuit 190 performs according to the electric circuit's intended function. It should be appreciated that said monitor and dichromatic LED are only examples and should not be regarded as limitations of the present invention. Those with ordinary skill in the art may design the first and second indicating unit 156 and 158 depending on the desired application.

In another aspect, the present disclosure is directed to a testing method. The testing method can test a printed circuit board, a printed circuit board assembly or the like, and may be applicable or readily adaptable to all technology.

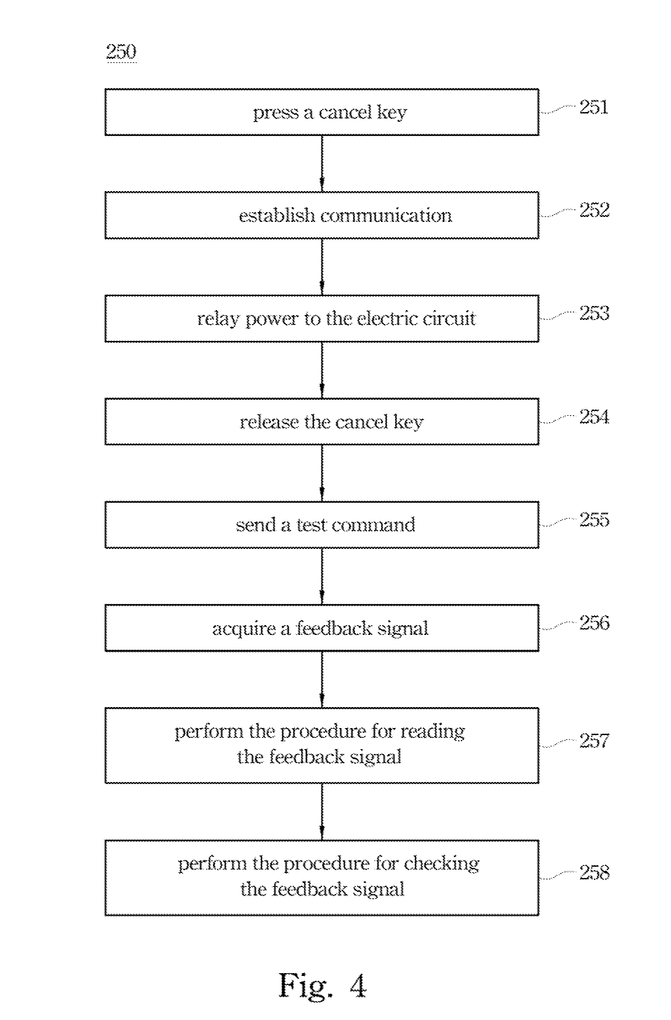

Please refer to FIG. 3 which is a flowchart illustrating a testing method 200 according to another embodiment of the present invention. The testing method 200 is adapted in in-circuit testing equipment. As shown in FIG. 3, the testing method 200 comprises the following steps 210, 220, 230, 240 and 250. The step 210 in the testing method 200 is to test whether an electric circuit is short or open circuits. The step 220 in the testing method 200 is to test solder joints of integrated circuits of the electric circuit. The step 230 in the testing method 200 is to test wiring lines of the electric circuit. The step 240 in the testing method 200 is to test protection diodes of the electric circuit. The step 250 in the testing method 200 is to test one or more functions of the electric circuit.

The in-circuit testing equipment can perform the steps 210, 220, 230, and 240 to test the hardware of the electric circuit. The processes of testing the hardware of the electric circuit are well known in the art and, thus, are not repeated herein.

In the step 250, the function of the electric circuit is tested after the hardware of the electric circuit passes the testing of the steps 210, 220, 230, and 240. For a more complete understanding of the step 250, please refer to FIG. 4 that is a flowchart of the step 250 of FIG. 3. As shown in FIG. 4, the step 250 may comprise the following sub-steps 251, 252, 253, 254, 255, 256, 257 and 258.

First, a cancel key of the in-circuit testing equipment is pressed in the sub-step 251, and then communication of the in-circuit testing equipment is established in the sub-step 252. In the sub-step 253, the electric circuit is supplied with power. Next, the cancel key is released in the sub-step 254. Then, a test instruction is sent to the electric circuit through the converter in the sub-step 255 wherein the converter is for converting signals, and a feedback signal is acquired through the converter in the sub-step 256. Then, one procedure is performed to read the feedback signal in the sub-step 257, and the following procedure is performed to check the feedback signal for determining whether the electric circuit performs according to the electric circuit's intended function in the sub-step 258.

Accordingly, the step 250 may be divided into a plurality of phases as follows. During the sub-steps 251, 252, 253 and 254, the in-circuit testing equipment is operated, and the electric circuit is supplied with power. During the sub-step 255, the test instruction is sent to the electric circuit through the converter, so that the electric circuit generates the feedback signal. During the sub-steps 256, 257 and 258, the feedback signal is received through the converter, and whether the electric circuit performs according to the electric circuit's intended function is analyzed according to the feedback signal.

The converter can electrically connect the electric circuit with the in-circuit testing equipment. In this embodiment, the converter is an RS-232-to-TTL converter. If the electric circuit itself had no chip of RS-232-to-TTL, the test instruction is sent to the electric circuit 190 through the RS-232-to-TTL converter during the sub-step 255, and furthermore the feedback signal is received through the RS-232-to-TTL converter to analyze whether the electric circuit performs according to the electric circuit's intended function during the sub-steps 256, 257 and 258. In an alternative embodiment, the converter may be a general purpose interface bus (GPIB) or the like.

The sub-step 258 may comprise a plurality of procedures as follows. The determination procedure is to check whether the feedback signal corresponds to response data after response data is stored, wherein the response data represents the feedback signal that is generated by the electric circuit while the electric circuit performs according to the electric circuit's intended function. Those with ordinary skill in the art may store the response data in the in-circuit testing equipment at a suitable time depending on the desired application; for example, the response data is preloaded before said determination procedure is performed. When it's determined that the feedback signal corresponds to the response data, one indication procedure is to indicate that the electric circuit performs according to the electric circuit's intended function; on the contrary, when it's determined that the feedback signal does not correspond to the response data, another indication procedure is to indicate that the electric circuit does not perform according to the electric circuit's intended function.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “steps of in the claims herein is not intended to invoke the provisions of 35 U.S.C. §112, 6th paragraph.

What is claimed is:

1. A testing apparatus comprising:
a converter electrically connected to at least one electric circuit and for converting signals; and
in-circuit testing equipment electrically connected to the converter, wherein the in-circuit testing equipment comprises:
an in-circuit testing module for testing hardware of the electric circuit;
a test instruction generation module for sending a test instruction to the electric circuit through the converter when the electric circuit is supplied with power and after the hardware of the electric circuit passes the test by the in-circuit testing module, so that the electric circuit generates a feedback signal; and
a feedback signal analysis module for receiving the feedback signal through the converter and analyzing, according to the feedback signal, whether the electric circuit performs according to the electric circuit's intended function.

2. The testing apparatus of claim 1, further comprising:
a relay for relaying electric power to the electric circuit.

3. The testing apparatus of claim 1, wherein the feedback signal analysis module comprises:
a database for storing response data;
a determining unit for determining whether the feedback signal corresponds to the response data; and
a first indicating unit for indicating that the electric circuit performs according to the electric circuit's intended function, when it's determined that the feedback signal corresponds to the response data.

4. The testing apparatus of claim 3, wherein the feedback signal analysis module further comprises:
a second indicating unit for indicating that the electric circuit does not perform according to the electric circuit's intended function, when it's determined that the feedback signal does not correspond to the response data.

5. The testing apparatus of claim 1, wherein the converter is an RS-232-to-TTL converter.

6. A testing method for in-circuit testing equipment, the testing method comprising:
testing hardware of an electric circuit;
sending a test instruction to the electric circuit through a converter when the electric circuit is supplied with power and after the hardware of the electric circuit passes the testing, so that the electric circuit generates a feedback signal, wherein the converter is for converting signals;
receiving the feedback signal through the converter; and
analyzing, according to the feedback signal, whether the electric circuit performs according to the electric circuit's intended function.

7. The testing method of claim 6, wherein the step of analyzing whether the electric circuit performs according to the electric circuit's intended function comprises:
storing response data;
determining whether the feedback signal corresponds to the response data; and
indicating that the electric circuit performs according to the electric circuit's intended function, when it's determined that the feedback signal corresponds to the response data.

8. The testing method of claim 7, wherein the step of analyzing whether the electric circuit performs according to the electric circuit's intended function further comprises:
indicating that the electric circuit does not perform according to the electric circuit's intended function, when it's determined that the feedback signal does not correspond to the response data.

9. The testing method of claim 6, wherein the converter is an RS-232-to-TTL converter.

10. A testing apparatus comprising:
a converter electrically connected to at least one electric circuit and for converting signals; and
in-circuit testing equipment electrically connected to the converter, wherein the in-circuit testing equipment comprises:
means for testing hardware of the electric circuit;
means for sending a test instruction to the electric circuit through the converter when the electric circuit is supplied with power and after the hardware of the electric circuit passes the test by the means for testing, so that the electric circuit generates a feedback signal; and
means for analyzing, according to the feedback signal, whether the electric circuit performs according to the electric circuit's intended function.

11. The testing apparatus of claim 10, further comprising:
means for relaying electric power to the electric circuit.

12. The testing apparatus of claim 10, wherein the means for analyzing whether the electric circuit performs according to the electric circuit's intended function comprises:
means for storing response data;
means for determining whether the feedback signal corresponds to the response data; and
means for indicating that the electric circuit performs according to the electric circuit's intended function, when it's determined that the feedback signal corresponds to the response data.

13. The testing apparatus of claim 12, wherein the means for analyzing whether the electric circuit performs according to the electric circuit's intended function further comprises:
means for indicating that the electric circuit does not perform according to the electric circuit's intended function, when it's determined that the feedback signal does not correspond to the response data.

14. The testing apparatus of claim 10, wherein the converter is an RS-232-to-TTL converter.
